(19) United States
(12) Patent Application Publication
(10) Pub. No.: US 2025/0125578 A1
(43) Pub. Date: Apr. 17, 2025

(54) COMPOSITE BODY AND AIRTIGHT PACKAGE COMPRISING COMPOSITE BODY

(71) Applicant: Nippon Electric Glass Co., Ltd., Shiga (JP)

(72) Inventors: Mitsuru TOMITA, Shiga (JP); Hiroki FUJITA, Shiga (JP)

(21) Appl. No.: 18/834,727

(22) PCT Filed: Jan. 20, 2023
(86) PCT No.: PCT/JP2023/001809

§ 371 Date: Jul. 31, 2024

(30) Foreign Application Priority Data
Feb. 3, 2022 (JP) 2022-015728

(51) Int. Cl. H01S 5/02257; H01S 5/02208; H01S 5/02253

(52) U.S. Cl. CPC H01S 5/02257; H01S 5/02208; H01S 5/02253

(57) ABSTRACT

A composite includes a frame body (5) and a lid body (6) arranged on the frame body (5). The lid body (6) is formed of glass capable of transmitting infrared light (L). The composite has a solder part (9) and a metal particle bonding part (10) arranged between the lid body (6) and the frame body (5). The lid body (6) and the frame body (5) are joined to each other via the solder part (9) and the metal particle joining part (9).

### TECHNICAL FIELD

The present invention relates to a composite and a hermetic package including the composite, and more particularly, to a technology for joining a lid body capable of transmitting infrared light and a frame body.

### BACKGROUND ART

For the purpose of, for example, protecting a device such as an LED from a surrounding environment, there has been known a structure called a hermetic package including a frame body and a lid body arranged on the frame body, in which a space defined by the lid body and the frame body is brought into an airtight state. In the structure of this kind, the lid body is desirably formed of glass having a high gas barrier property so that airtightness is maintained for a long period of time (see Patent Literature 1 in each case).

### CITATION LIST

### Patent Literature

[PTL 1] JP 2020-1958 A
[PTL 2] JP 6417199 B2
[PTL 3] JP 2011-141158 A

### SUMMARY OF THE INVENTION

### Technical Problem

Incidentally, as an apparatus including the above-mentioned device, an apparatus including a laser device that emits infrared light has been known (see, for example, Patent Literature 2). Also in the apparatus of this kind, it is important that a space in which the laser device is placed be kept in an airtight state, and hence the application of the above-mentioned hermetic package is considered to be desired. Meanwhile, when the laser device capable of emitting infrared light is protected with the hermetic package as described above, there is a need for a composite obtained by bonding a lid body and a frame body, the lid body being formed of a material capable of transmitting infrared light. However, the material of this kind generally has poor adhesiveness to another substance, and hence it is difficult to join the lid body and the frame body under the state in which the lid body and the frame body are sufficiently brought into close contact with each other, by ordinary joining means.

In this regard, in, for example, Patent Literature 3, there has been proposed a method of joining an infrared ray transmitting window made of glass to a can made of a metal serving as a frame body through use of solder having a low melting point. With the solder, airtightness can be ensured in a joining part between the window made of glass and the can made of a metal. However, when the solder is used as a joining material, the solder inevitably undergoes phase transition in association with melting. Accordingly, when heating is performed under the state in which the lid body is placed at a predetermined position on the frame body, positional displacement of the lid body may occur during the heating.

In view of the above-mentioned circumstances, a technical object to be achieved by the present invention is to provide a composite in which a lid body and a frame body are joined to each other so that excellent airtightness can be imparted to a space defined by the lid body and the frame body, while positional displacement of the lid body is prevented.

### Solution to Problem

The above-mentioned object can be achieved by a composite according to one embodiment of the present invention. That is, according to one embodiment of the present invention, there is provided a composite, comprising: a frame body; and a lid body arranged on the frame body, wherein the lid body is formed of glass capable of transmitting infrared light, wherein the composite has a solder part and a metal particle bonding part arranged between the lid body and the frame body, and wherein the lid body and the frame body are joined to each other via the solder part and the metal particle joining part.

In the composite according to the one embodiment of the present invention, when the solder part and the metal particle bonding part are arranged between the lid body and the frame body serving as targets to be joined as described above, the influence of positional displacement caused by phase transition in association with melting of the solder part can be reduced by the metal particle bonding part. In addition, a reduction in airtightness due to inner pores of the metal particle bonding part can be avoided by virtue of high airtightness of the solder part.

In addition, in the composite according to the one embodiment of the present invention, the metal particle bonding part may be formed on an entirety of a peripheral edge of the lid body. In addition, in this case, the solder part may be arranged on an outside of the metal particle bonding part.

When the lid body is formed of the glass capable of transmitting infrared light, a region (center region) of the lid body excluding the peripheral edge is generally used as an infrared light transmitting region. Accordingly, when the metal particle bonding part is formed on the entirety of the peripheral edge of the lid body, and the solder part is arranged on the outside of the metal particle bonding part, flowing of the solder part toward an inside (infrared light transmitting region side) can be suppressed by the metal particle bonding part. Accordingly, a situation in which the solder part flows into the infrared light transmitting region of the lid body is reliably prevented, and an infrared light transmitting function can be ensured.

In addition, in the composite according to the one embodiment of the present invention, the solder part may be brought into contact with the metal particle bonding part.

When the solder part and the metal particle bonding part are arranged so as to be brought into contact with each other as described above, atomic diffusion occurs between a metal for forming the solder part and a metal for forming each metal particle. Particularly under the state in which the solder part is melted to be liquefied, diffusion of a metal atom for forming each metal particle into the solder part is promoted. Accordingly, the characteristics of the metal for forming each metal particle, such as an increasing effect on the melting point of the solder part and an increasing effect on the ductility thereof, are imparted to the solder part, and the characteristics required for the solder part serving as a joining part can be improved.

In addition, in the composite according to the one embodiment of the present invention, the solder part may be formed of one or more kinds of metals selected from In, Sn, Bi, Ag, and Au.

When the appropriate one or more kinds of metals are used as the metal for forming the solder part as described above, predetermined characteristics can be imparted to the joining part (solder part) between the lid body and the frame body. In addition, when a metal having a relatively low melting point is used, the solder part can be melted at relatively low temperature. Accordingly, the lid body and the frame body can be joined to each other while the influence of heat on the lid body and the frame body to be joined via the solder part, or on a member (e.g., an optical device or a component including the optical device) to be arranged in a space defined by the lid body and the frame body is minimized.

In addition, in the composite according to the one embodiment of the present invention, metal particles of the metal particle bonding part may each be formed of one or more kinds of metals selected from Au, Ag, and Cu.

When the metal particles of the metal particle bonding part are each formed of the above-mentioned one or more kinds of metals as described above, excellent characteristics can be imparted to the joining part (metal particle bonding part) between the lid body and the frame body. In addition, the metal particles of the metal particle bonding part can be bonded to each other by a sintering action depending on formulation. Accordingly, strong metal bonding can be obtained even at relatively low temperature, and thus the lid body and the frame body can be firmly joined to each other.

In addition, in the composite according to the one embodiment of the present invention, the glass capable of transmitting infrared light may comprise glass having an internal transmittance in a wavelength range of from 3 μm to 14 μm of 90% or more at a thickness of 2 mm.

When the glass capable of transmitting infrared light is selected as described above, infrared light can be transmitted sufficiently. Accordingly, an infrared light transmitting characteristic required for the lid body can be ensured.

In addition, in the composite according to the one embodiment of the present invention, the glass capable of transmitting infrared light may comprise chalcogenide glass.

In this case, the chalcogenide glass may comprise, in terms of mole percent, 50% to 80% of S, 0% to 40% of Sb, provided that 0% is excluded, 0% to 18% of Ge, provided that 0% is excluded, 0% to 20% of Sn, and 0% to 20% of Bi.

Alternatively, the chalcogenide glass may comprise, in terms of mole percent, 4% to 80% of Te, 0% to 50% of Ge, provided that 0% is excluded, and 0% to 20% of Ga.

When the chalcogenide glass is adopted as the glass capable of transmitting infrared light as described above, a satisfactory infrared light transmitting characteristic can be achieved. In addition, with the chalcogenide glass, which is inexpensive as compared to any other infrared light transmitting material such as Ge, the composite of the lid body and the frame body can be produced at a low cost.

According to the one embodiment of the present invention, the lid body can be joined to the frame body so that excellent airtightness can be imparted to the space defined by the lid body and the frame body, while positional displacement of the lid body is prevented. Accordingly, the composite according to the one embodiment of the present invention is suitable as, for example, a composite in which at least part of the lid body comprises a window capable of transmitting infrared light.

Alternatively, the composite according to the one embodiment of the present invention is suitable as a composite in which at least part of the lid body comprises a window capable of transmitting infrared light.

Alternatively, the composite according to the one embodiment of the present invention is suitable as a hermetic package, comprising: a base body having a main surface; and the composite arranged on the main surface of the base body.

### Advantageous Effects of Invention

As described above, according to the present invention, the lid body can be joined to the frame body so that excellent airtightness can be imparted to the space defined by the lid body and the frame body, while positional displacement of the lid body is prevented.

### BRIEF DESCRIPTION OF DRAWINGS

FIG. 1 is a sectional view of an electronic apparatus formed of a hermetic package comprising a composite according to one embodiment of the present invention.

FIG. 2 is a plan view of the electronic apparatus of FIG. 1.

FIG. 3 is an enlarged sectional view of a portion indicated by the arrow A of FIG. 1.

FIG. 4 is an enlarged sectional view of a portion indicated by the arrow B of FIG. 3.

FIG. 5A is a view for conceptually illustrating a production step for the composite of FIG. 1, and is a sectional view for conceptually illustrating a silicon film formation step.

FIG. 5B is a view for conceptually illustrating a production step for the composite of FIG. 1, and is a sectional view for conceptually illustrating a metallized film formation step.

FIG. 5C is a view for conceptually illustrating a production step for the composite of FIG. 1, and is a sectional view for conceptually illustrating a solder material and metal paste material supply step.

FIG. 5D is a view for conceptually illustrating a production step for the composite of FIG. 1, and is a sectional view for conceptually illustrating a setting step.

### DESCRIPTION OF EMBODIMENTS

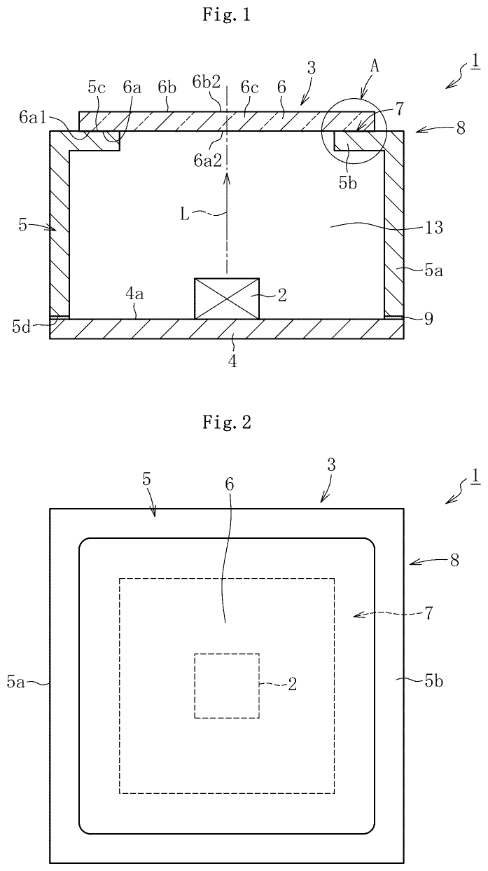

One embodiment of the present invention is described with reference to FIG. 1 to FIG. 5D below. In the following description, the terms “upper” and “lower” are merely specified for convenience in order to facilitate understanding of the description, and do not limit an actual use mode or placement mode.

FIG. 1 is a sectional view of an electronic apparatus 1 according to this embodiment. The electronic apparatus 1 comprises an electronic component 2, and a hermetic package 3 in which the electronic component 2 is stored.

In this embodiment, the electronic component 2 is, for example, a laser device that emits infrared light L. An example of the laser device is a quantum cascade laser device. When the electronic component 2 is a quantum cascade laser device, the electronic apparatus 1 is constructed together with any other necessary component (not shown) so that the apparatus can be utilized as, for example, a gas analyzing apparatus or a precision machining apparatus. In addition, the electronic component 2 may be a light receiving device capable of receiving the infrared light L. For example, any appropriate device, such as a bolometer-type, thermopile-type, pyroelectric-type, or quantum-type (Mercury Cadmium Telluride, InSb, or Type III Super-Lattice) device, may be selected as the light receiving device in accordance with applications.

The hermetic package 3 comprises: a base body 4 in which the electronic component 2 is arranged on its main surface 4a; a frame body 5 arranged on the main surface 4a of the base body 4 so as to surround the electronic component 2; a lid body 6 arranged on the frame body 5; and a joining part 7 formed between the frame body 5 and the lid body 6. In this case, the frame body 5 and the lid body 6, and the joining part 7 form a composite 8 according to the present invention.

The frame body 5 integrally has: a tubular part 5a arranged on the main surface 4a of the base body 4; and an inner flange part 5b extending from an upper end of the tubular part 5a toward a center side. In this case, while a vertically lower end side of the frame body 5 is closed with the base body 4, a vertically upper end side thereof is closed with the lid body 6. In this embodiment, the frame body 5 (tubular part 5a) forms a square tubular shape as illustrated in FIG. 2, but may form any other shape, such as a cylindrical shape, an elliptic tubular shape, or a polygonal tubular shape.

When a sufficient joining area can be ensured between an upper end surface of the tubular part 5a and a lower surface 6a of the lid body 6, the inner flange part 5b may be omitted. In this case, the joining part 7 is formed between the upper end surface of the tubular part 5a and the lower surface 6a of the lid body 6 (not shown).

The base body 4 and the frame body 5 are each formed of, for example, a ceramic, such as aluminum nitride or aluminum oxide, glass, a glass ceramic, a silicon compound such as silicon, or a metal including Co, Ni, Fe, Ag, Cu, W, or Mo. In this embodiment, the base body 4 and the frame body 5 are both formed of the metal. When the base body 4 and the frame body 5 are formed of the same material, the base body 4 and the frame body 5 may be integrally formed, or may be formed as separate bodies and integrated (joined). When the base body 4 and the frame body 5 (tubular part 5a) are joined to each other, any joining means, such as laser joining, solder joining, or glass frit joining, may be adopted.

The lid body 6 generally forms a sheet shape, and has the flat lower surface 6a. The lid body 6 is joined under the state in which the flat lower surface 6a is placed on an upper surface 5c of the inner flange part 5b of the frame body 5. In other words, the joining part 7 is formed between the lower surface 6a of the lid body 6 and the upper surface 5c of the frame body 5. The shape of the lid body 6 is any appropriate shape, and is appropriately set in accordance with characteristics required for the lid body 6. For example, in this embodiment, center regions 6a2 and 6b2 of the lower surface 6a and an upper surface 6b of the lid body 6 are formed into flat shapes so that a center region 6c of the lid body 6 functions as a window for transmitting infrared light.

The lid body 6 is formed of glass capable of transmitting the infrared light L. Specifically, the glass capable of transmitting the infrared light L is glass showing an internal transmittance in a wavelength range of from 3 μm to 14 μm of from 70% to 99% (preferably 90% or more) and an internal transmittance in a wavelength range of from 0.4 μm to 0.8 μm of 2% or less at a thickness of 2 mm. The internal transmittance may be measured, for example, with UH-4150 manufactured by Hitachi High-Tech Corporation.

An example of the glass having the above-mentioned characteristics may be chalcogenide glass. In this case, the chalcogenide glass may comprise, in terms of mole percent, 50% to 80% of S, 0% to 40% of Sb, provided that 0% is excluded, 0% to 18% of Ge, provided that 0% is excluded, 0% to 20% of Sn, and 0% to 20% of Bi.

The content of S in the chalcogenide glass in terms of mole percent is preferably 55% or more, more preferably 60% or more, and is preferably 75% or less, more preferably 70% or less. When the content of S in the glass is less than 50%, vitrification is difficult. Meanwhile, when the content of S in the glass is more than 80%, the glass has reduced weather resistance, and hence the environment in which the electronic apparatus 1 is used is restricted. The content of S is set within an appropriate numerical range from the above-mentioned viewpoints.

The content of Sb in the chalcogenide glass in terms of mole percent is preferably 5% or more, more preferably 10% or more, and is preferably 35% or less, more preferably 33% or less. When the glass is free of Sb or the content of Sb therein is more than 40%, vitrification is difficult.

The content of Ge in the chalcogenide glass in terms of mole percent is preferably 2% or more, more preferably 4% or more, and is preferably 20% or less, more preferably 15% or less. When the glass is free of Ge, vitrification is difficult. Meanwhile, when the content of Ge in the glass is more than 18%, a Ge-based crystal is precipitated from the glass, and hence it is difficult to express the above-mentioned internal transmittance.

The content of Sn in the chalcogenide glass in terms of mole percent is preferably 1% or more, more preferably 5% or more, and is preferably 15% or less, more preferably 10% or less. Sn in the glass is a component that promotes vitrification. However, when the content of Sn in the glass is more than 20%, vitrification is difficult.

The content of Bi in the chalcogenide glass in terms of mole percent is preferably 0.5% or more, more preferably 2% or more, and is preferably 10% or less, more preferably 8% or less. Bi in the glass is a component that reduces energy required for a raw material to vitrify at the time of the melting of the glass. Meanwhile, when the content of Bi in the glass is more than 20%, a Bi-based crystal is precipitated from the glass, and hence it is difficult to express the above-mentioned internal transmittance.

The chalcogenide glass is not limited to the above-mentioned composition, and may comprise, in terms of mole percent, 4% to 80% of Te, 0% to 50% of Ge, provided that 0% is excluded, and 0% to 20% of Ga.

The content of Te in the chalcogenide glass in terms of mole percent is preferably 10% or more, more preferably 20% or more, and is preferably 75% or less, more preferably 70% or less. When the content of Te in the glass is less than 4%, vitrification is difficult. Meanwhile, when the content of Te in the glass is more than 80%, a Te-based crystal is precipitated from the glass, and hence it is difficult to express the above-mentioned internal transmittance.

The content of Ge in the chalcogenide glass in terms of mole percent is preferably 1% or more, more preferably 5% or more, and is preferably 40% or less, more preferably 30% or less. When the glass is free of Ge, vitrification is difficult. Meanwhile, when the content of Ge in the glass is more than 50%, a Ge-based crystal is precipitated from the glass, and hence it is difficult to express the above-mentioned internal transmittance.

The content of Ga in the chalcogenide glass in terms of mole percent is preferably 0.1% or more, more preferably 1% or more, and is preferably 15% or less, more preferably 10% or less. When the glass comprises Ga, a vitrification range can be widened, resulting in enhanced thermal stability of the glass (stability in vitrification).

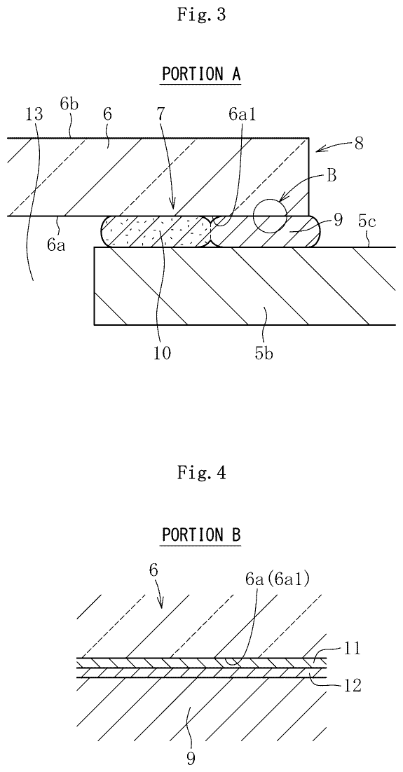

There is formed, between the lower surface 6a of the lid body 6 and the upper surface 5c of the frame body 5, the joining part 7 that joins the lower surface 6a and the upper surface 5c to each other. Herein, as illustrated in FIG. 3, the joining part 7 comprises a solder part 9 and a metal particle bonding part 10. That is, the lower surface 6a of the lid body 6 and the upper surface 5c of the frame body 5 are joined to each other via the solder part 9, and are also joined to each other via the metal particle bonding part 10. In this embodiment, the solder part 9 is arranged on the entirety of a peripheral edge of the lid body 6. Similarly, the metal particle bonding part 10 is arranged on the entirety of the peripheral edge of the lid body 6.

In addition, in this embodiment, as illustrated in FIG. 3, the solder part 9 is arranged on an outside of the metal particle bonding part 10. In other words, the metal particle bonding part 10 is arranged on a side relatively closer to the center region 6c of the lid body 6, and the solder part 9 is arranged on a side relatively farther from the center region 6c of the lid body 6.

In addition, in this embodiment, the solder part 9 and the metal particle bonding part 10 are brought into contact with each other. As illustrated in FIG. 3, when the solder part 9 is arranged on the outside of the metal particle bonding part 10, an outside portion of the metal particle bonding part 10 and an inside portion of the solder part 9 are brought into contact with each other. With this configuration, a metal atom of the metal particle bonding part 10 can blend and diffuse into the solder part 9 in production steps described later. Thus, the solder part 9 is not only improved in heat resistance by virtue of an increase in melting point, but also improved in mechanical characteristics such as shock resistance by virtue of an increase in ductility.

The thickness dimension of the solder part 9 is preferably 1 μm or more and 200 μm or less, more preferably 10 μm or more and 100 μm or less, still more preferably 20 μm or more and 50 μm or less.

Similarly, the thickness dimension of the metal particle bonding part 10 is preferably 1 μm or more and 200 μm or less, more preferably 10 μm or more and 100 μm or less, still more preferably 20 μm or more and 50 μm or less.

Any known solder material may be adopted as a material of the solder part 9 (solder material). For example, the solder part 9 may be formed of one or more kinds of metals selected from In, Sn, Bi, Ag, Au, and Pb. In addition, as a solder material that can be used (melted) at relatively low temperature (e.g., less than 250° C.), Sn—Bi-based solder, Sn—In-based solder, Sn—Ag-based solder, or the like is suitable.

The metal particle bonding part 10 forms a structure in which a plurality of metal particles are bonded to each other. Metal particles each formed of any metal (including an alloy) may be adopted as the metal particles. For example, metal particles each formed of one or more kinds of metals selected from Au, Ag, and Cu are suitable. In addition, the metal particles each principally have any appropriate particle diameter, and micro-level or nano-level metal particles may be adopted.

The metal particle bonding part 10 is obtained, for example, by heating a material (e.g., a paste material) containing the metal particles having the above-mentioned configuration and a solvent to remove the solvent, to thereby promote a sintering action of the metal particles. In this case, a heating temperature (sintering temperature of the metal particles) is appropriately set in consideration of the composition of the metal particles, the particle diameters thereof, and the melting point of the solder part 9. That is, it is desired that the composition of the metal particles, the particle diameters thereof, and the like be set so that the sintering temperature is lower than the melting point (melting temperature) of the solder part 9.

In addition, in this embodiment, the lower surface 6a of the lid body 6 has a silicon layer 11 (see FIG. 4). The glass (e.g., chalcogenide glass) capable of transmitting infrared light for forming the lid body 6 has poor adhesiveness or a poor joining property to any other substance, but may show satisfactory adhesiveness or a satisfactory joining property to the silicon layer 11. Accordingly, when the silicon layer 11 is interposed between the solder part 9 and the lid body 6, the solder part 9 can be brought into close contact with the lid body 6.

The silicon layer 11 is formed on a peripheral edge region 6a1 of the lower surface 6a of the lid body 6, for example, by vapor deposition or sputtering. At this time, the silicon layer 11 is desirably formed on the entirety (entire circumference) of the peripheral edge region 6a1. The thickness dimension of the silicon layer 11 is preferably 0.01 μm or more and 5 μm or less, more preferably 0.03 μm or more and 1 μm or less, still more preferably 0.05 μm or more and 0.50 μm or less.

In addition, in this embodiment, the lower surface 6a of the lid body 6 further has a metallized layer 12 (see FIG. 4). That is, in this case, the lid body 6 forms a structure in which the silicon layer 11 is formed on the lower surface 6a of the lid body 6, and the metallized layer 12 is further formed on the surface of the silicon layer 11. The metallized layer 12 may show satisfactory adhesiveness or a satisfactory joining property to the silicon layer 11 (silicon). In addition, the metallized layer 12 may show satisfactory adhesiveness or a satisfactory joining property to the solder part 9 (solder). Accordingly, when the silicon layer 11, the metallized layer 12, and the solder part 9 are arranged in the stated order from a lid body 6 side, the frame body 5 and the lid body 6, which are each brought into contact with the solder part 9, can be firmly joined to each other. In addition, the airtightness of a space defined by the frame body 5 and the lid body 6 (space 13 in the hermetic package 3) can be improved to a required level.

The metallized layer 12 is formed on the surface of the silicon layer 11, for example, by vapor deposition or sputtering. At this time, the metallized layer 12 is desirably formed on the entirety of the surface of the silicon layer 11. The thickness dimension of the metallized layer 12 is preferably 0.1 μm or more and 10 μm or less, more preferably 0.3 μm or more and 5 μm or less, still more preferably 0.5 μm or more and 3 μm or less.

For example, Cr, Ti, Ni, Pt, Au, Co, or an alloy thereof may be adopted as a material of the metallized layer 12. In addition, the structure of the metallized layer 12 is not particularly limited, and a single layer formed of the above-mentioned material, or a multilayer structure formed of different materials may be adopted.

Before the formation of the silicon layer 11, an antireflection film (not shown) may be formed on one or more main surfaces of the lid body 6 (at least one of the lower surface 6a or the upper surface 6b). With this configuration, reflection of light via the lid body 6 can be suppressed. For example, a film formed of at least one or more kinds selected from Ge, Si, a fluoride, ZnSe, ZnS, and diamond-like carbon is preferred as the antireflection film. The antireflection film may be formed, for example, by a vapor deposition method or a sputtering method. In addition, the thickness of the antireflection film is, for example, 1.0 μm or more and 5.0 μm or less.

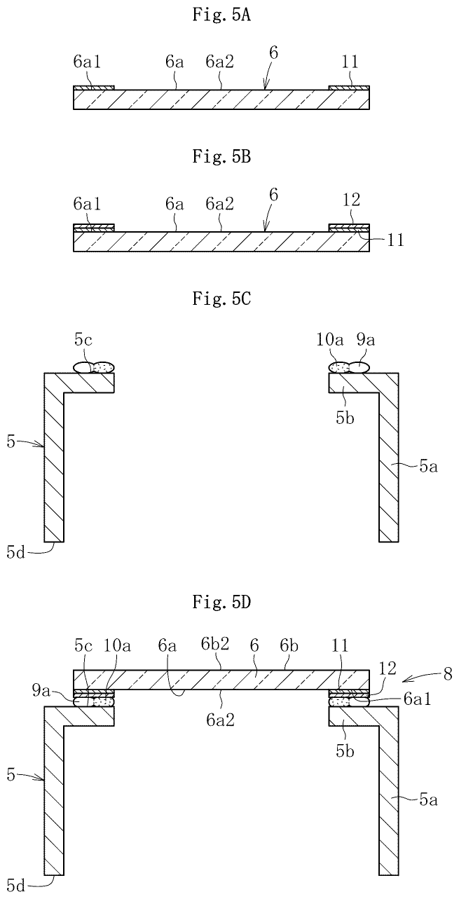

Next, examples of methods of producing the composite 8, the hermetic package 3, and the electronic apparatus 1 having the above-mentioned configurations are described mainly with reference to FIG. 5A to FIG. 5D.

A method of producing the composite 8 according to this embodiment comprises: a silicon layer formation step S1 of forming the silicon layer 11 on the surface of the lid body 6; a metallized layer formation step S2 of forming the metallized layer 12 on the surface of the silicon layer 11; a material supply step S3 of supplying a material of the joining part 7 to the surface of the frame body 5; a setting step S4 of setting the lid body 6 at a predetermined position on the frame body 5; and a joining part formation step S5 of heating the material of the joining part 7 to form the joining part 7. In addition, methods of producing the hermetic package 3 and the electronic apparatus 1 each comprise the above-mentioned steps S1 to S5, and further a joining step S6 of joining the base body 4 to the frame body 5. The details about the steps S1 to S6 are described below sequentially.

### (S1) Silicon Layer Formation Step

In this step S1, the silicon layer 11 is formed on a surface of the lid body 6 that forms a predetermined shape, specifically on the peripheral edge region 6a1 of the lower surface 6a (see FIG. 5A). For example, when the silicon layer 11 is formed by vapor deposition, the lid body 6 and a silicon material are carried into a vacuum vessel of a vapor deposition apparatus, and the silicon material is heated under a vacuum atmosphere to be vaporized. Thus, a silicon molecule having been vaporized is deposited on the lower surface 6a (particularly, the peripheral edge region 6a1) of the lid body 6, to thereby form the silicon layer 11 having a predetermined thickness on the lower surface 6a.

### (S2) Metallized Layer Formation Step

In this step S2, the metallized layer 12 is formed on the surface of the silicon layer 11 formed on the lower surface 6a of the lid body 6 obtained in the step S1 (see FIG. 5B). For example, when the metallized layer 12 is formed by vapor deposition, the metallized layer 12 having a predetermined thickness is formed on the silicon layer 11 in the same manner as in the step S1. Thus, the lid body 6 in which the silicon layer 11 and the metallized layer 12 are formed on the peripheral edge region 6a1 of the lower surface 6a under the state of overlapping each other is obtained.

### (S3) Material Supply Step

In this step S3, the material of the joining part 7 is supplied to a predetermined surface of the frame body 5 serving as a target to be joined. Specifically, first, as illustrated in FIG. 5C, the frame body 5 is prepared. Then, a solder material 9a, which is a material of the solder part 9 serving as the joining part 7, is supplied to the upper surface 5c of the frame body 5. In this case, the solder material 9a is supplied to the entire circumferential region of the upper surface 5c. In addition, a metal paste material 10a, which is a material of the metal particle bonding part 10 serving as the joining part 7, is supplied to the upper surface 5c of the frame body 5. Also in this case, the metal paste material 10a is supplied to the entire circumferential region of the upper surface 5c. In this embodiment, supply ranges of the solder material 9a and the metal paste material 10a are set so that the solder material 9a is positioned on the outside of the metal paste material 10a, and the solder material 9a and the metal paste material 10a are brought into contact with each other. While the case in which the solder material 9a and the metal paste material 10a are supplied to the upper surface 5c of the frame body 5 has been described in this embodiment, the solder material 9a and the metal paste material 10a may be supplied to the lower surface 6a of the lid body 6 obtained in the step S1 or the step S2.

### (S4) Setting Step

In this step S4, the lid body 6 produced in the step S2 is set at a predetermined position on the frame body 5 obtained in the step S3. At this time, the lid body 6 is set at a predetermined position on the frame body 5 under the state of being positioned in a horizontal direction so that the entire regions of the silicon layer 11 and the metallized layer 12 formed on the lower surface 6a of the lid body 6 are brought into contact with the solder material 9a and the metal paste material 10a supplied to the upper surface 5c of the frame body 5 (see FIG. 5D).

### (S5) Joining Part Formation Step

After the lid body 6 is set as described above, the frame body 5 and the lid body 6 are carried into, for example, a heating furnace and heated to a predetermined temperature. In this embodiment, first, the frame body 5 and the lid body 6 are heated to a temperature (i.e., a sintering temperature) at which the metal paste material 10a supplied onto the frame body 5 can express joining strength. Thus, while a solvent in the metal paste material 10a is removed, metal particles in the metal paste material 10a aggregate with each other to cause a sintered bond therebetween. As a result, the metal particle bonding part (herein, sintered metal part) 10 is formed between the frame body 5 and the lid body 6.

After the metal particle bonding part 10 is formed as described above, subsequently, the frame body 5 and the lid body 6 are heated and increased in temperature to a temperature at which the solder material 9a is melted. Thus, the solder material 9a is melted to become a state of being brought into close contact with the upper surface 5c of the frame body 5 and the lower surface 6a of the lid body 6 (in this case, the surface of the metallized layer 12). After that, the heating is stopped (or the frame body 5 and the lid body 6 are reduced in temperature) to solidify the solder material 9a. As a result, the solder part 9 in the state of being brought into close contact with the frame body 5 and the lid body 6 (in this case, the metallized layer 12) is formed between the frame body 5 and the lid body 6. Thus, the composite 8 comprising the frame body 5 and the lid body 6, and the joining part 7 is obtained.

At this time, when the solder material 9a and the metal paste material 10a are brought into contact with each other, a metal atom in each metal particle diffuses into the solder material 9a in a liquefied state during formation of the metal particle bonding part 10 from the metal paste material 10a. Thus, the metal structure of the solder part 9 is changed, and for example, the characteristics of a metal for forming each metal particle are imparted thereto, to thereby improve the characteristics (e.g., melting point and ductility) of the solder part 9. Specifically, the solder part 9 is improved in heat resistance by virtue of an increase in melting point, and is also improved in mechanical characteristics such as shock resistance by virtue of an increase in ductility.

### (S6) Joining Step

After that, a lower end surface 5d of the tubular part 5a of the frame body 5 of the composite 8 is placed on the base body 4 having the electronic component 2 mounted thereto. At this time, a solder material serving as a joining material is applied to each of the base body 4 and the lower end surface 5d of the frame body 5, and after the placement, the base body 4 and the frame body 5 are heated and increased in temperature to a temperature at which the solder material is melted. Thus, the solder material is melted to become a state of being brought into close contact with the base body 4 and the frame body 5. After that, the heating is stopped (or the base body 4 and the frame body 5 are reduced in temperature) to solidify the solder material. As a result, the solder part 9 in the state of being brought into close contact with the base body 4 and the frame body 5 is formed between the base body 4 and the frame body 5. Thus, the hermetic package 3 comprising the base body 4, the frame body 5, and the lid body 6, and the electronic apparatus 1, which is the hermetic package 3 in which the electronic component 2 is stored, are obtained (see FIG. 1 in both cases).

Alternatively, other than the above-mentioned procedure, the following steps may be adopted. First, the electronic component 2 is prepared on the base body 4 of a structure in which the base body 4 and the frame body 5 are integrated with each other. Then, the solder material 9a, which is the material of the solder part 9 serving as the joining part 7, is supplied to the upper surface 5c of the frame body 5, and the metal paste material 10a, which is the material of the metal particle bonding part 10 serving as the joining part 7, is supplied to the upper surface 5c of the frame body 5, and further, the lid body 6 is placed so as to cover the upper surface 5c. After that, the structure and the lid body 6 are carried into, for example, a heating furnace and heated to a predetermined temperature. After that, the heating is stopped (or the structure and the lid body 6 are reduced in temperature). Thus, the hermetic package 3 comprising the base body 4, the frame body 5, and the lid body 6, and the electronic apparatus 1, which is the hermetic package 3 in which the electronic component 2 is stored, can be obtained. With this configuration, a process for obtaining the composite 8 serving as an intermediate and a process for obtaining the hermetic package 3 (electronic apparatus 1) serving as a final product can be simultaneously performed. Also in this case, the solder material 9a and the metal paste material 10a may be supplied to the lower surface 6a of the lid body 6 obtained in the step S1.

As described above, in the composite 8 and the hermetic package 3 according to this embodiment, the solder part 9 and the metal particle bonding part 10 are arranged between the lid body 6 and the frame body 5 serving as targets to be joined. The metal particle bonding part 10 does not undergo phase transition in association with melting, and hence has substantially no risk of causing positional displacement at the time of joining. Accordingly, in the setting step S4, the lid body 6 can be joined to the frame body 5 under the state in which the position of the lid body 6 is kept. In addition, when the solder part 9 is arranged between the lid body 6 and the frame body 5, the internal space 13 of the hermetic package 3 defined by the lid body 6 and the frame body 5 can be hermetically sealed by virtue of the effect of the solder part 9 having high airtightness. Accordingly, in the composite 8 and the hermetic package 3 according to this embodiment, while the lid body 6 can be accurately fixed to a predetermined position on the frame body 5, excellent airtightness can be imparted to the internal space 13 of the hermetic package 3. In addition, the lid body 6 and the frame body 5 are joined to each other via the solder part 9 and the metal particle bonding part 10, and hence sufficiently high joining strength can be achieved between the lid body 6 and the frame body 5.

In addition, in this embodiment, while the metal particle bonding part 10 is formed on the entirety of the peripheral edge of the lid body 6, the solder part 9 is arranged on the outside of the metal particle bonding part 10. Thus, flowing of the solder part 9 (solder material 9a) toward the center region 6c of the lid body 6, which serves as an infrared light L transmitting region, can be suppressed by the metal particle bonding part 10. Accordingly, a situation in which the solder part 9 flows into the infrared light L transmitting region of the lid body 6 is reliably prevented, and an infrared light L transmitting function can be ensured.

While the one embodiment of the present invention has been described above, the composite and the hermetic package comprising the composite, and the method of producing the composite and the method of producing the hermetic package comprising the composite according to the present invention are not limited to the above-mentioned embodiment, and various modes may be adopted within the scope of the present invention.

While, for example, the case in which both the solder part 9 and the metal particle bonding part 10 are formed on the entirety of the peripheral edge of the lid body 6 has been given as an example in the above-mentioned embodiment, it is needless to say that the present invention is not limited to this configuration. For example, when there is no need to consider flowing of the solder part 9 (solder material 9a) toward the infrared light L transmitting region, it is not required that the metal particle bonding part 10 be arranged on the entirety of the peripheral edge of the lid body 6, and it is also not required that the metal particle bonding part 10 be arranged on an inside with respect to the solder part 9. That is, the metal particle bonding part 10 can adopt any configuration as long as the effect of preventing positional displacement of the lid body 6 and the effect of expressing joining strength between the lid body 6 and the frame body 5 can be exhibited.

In addition, while the case in which the lower surface 6a of the lid body 6, which is arranged on a joining part 7 side, has a flat shape in its entirety has been given as an example in the above-mentioned embodiment, the form of the lid body 6 is not limited thereto. For example, although not shown, the lid body 6 may be formed so that the peripheral edge region 6a1 of the lower surface 6a of the lid body 6, which serves as a joining part 7 formation region, is closer to an upper surface 6b side than the center region 6a2. In other words, the peripheral edge region of the lid body 6 may be formed to have a smaller thickness than the center region 6c. Alternatively, there may be adopted a configuration in which flowing of the solder part 9 (solder material 9a) toward the infrared light L transmitting region can be prevented, for example, by forming an annular groove on at least one of the lower surface 6a of the lid body 6 or the upper surface 5c of the frame body 5.

In addition, while the case in which the center region 6c of the lid body 6 is flat on both the front and back surfaces thereof, and functions as a window capable of transmitting the infrared light L as it is has been given as an example in the above-mentioned description, the present invention is not limited thereto. For example, although not shown, the present invention may be applied to a case in which the center regions 6a2 and 6b2 of the lower surface 6a and the upper surface 6b of the lid body 6 form a predetermined concave curved surface and a predetermined convex curved surface, respectively, so that the center region 6c of the lid body 6 functions as a lens.

In addition, while the case in which the present invention is applied to the electronic apparatus 1 in which the electronic component 2 is a laser device (e.g., quantum cascade laser device) that emits the infrared light L has been given as an example in the above-mentioned description, it is needless to say that the application target of the present invention is not limited thereto. For example, the present invention may also be applied to the electronic apparatus 1 in which the electronic component 2 is a light receiving device that receives the infrared light L.

### REFERENCE SIGNS LIST

1 electronic apparatus
2 electronic component
3 hermetic package
4 base body
4a main surface
5 frame body
5a tubular part
5b inner flange part
5c upper surface
5d lower end surface
6 lid body
6a lower surface
6a1 peripheral edge region
6a2, 6b2 center region
6b upper surface
6c center region
7 joining part
8 composite
9 solder part
9a solder material
10 metal particle bonding part
10a metal paste material
11 silicon layer
12 metallized layer
13 internal space
L infrared light
S1 silicon layer formation step
S2 metallized layer formation step
S3 material supply step
S4 setting step
S5 joining part formation step

1. A composite, comprising:
a frame body; and
a lid body arranged on the frame body,
wherein the lid body is formed of glass capable of transmitting infrared light,
wherein the composite has a solder part and a metal particle bonding part arranged between the lid body and the frame body, and
wherein the lid body and the frame body are joined to each other via the solder part and the metal particle joining part.

2. The composite according to claim 1,
wherein the metal particle bonding part is formed on an entirety of a peripheral edge of the lid body, and
wherein the solder part is arranged on an outside of the metal particle bonding part.

3. The composite according to claim 1, wherein the solder part is brought into contact with the metal particle bonding part.

4. The composite according to claim 1, wherein the solder part is formed of one or more kinds of metals selected from In, Sn, Bi, Ag, and Au.

5. The composite according to claim 1, wherein metal particles of the metal particle bonding part are each formed of one or more kinds of metals selected from Au, Ag, and Cu.

6. The composite according to claim 1, wherein the glass capable of transmitting infrared light comprises glass having an internal transmittance in a wavelength range of from 3 μm to 14 μm of 90% or more at a thickness of 2 mm.

7. The composite member according to claim 1, wherein the glass capable of transmitting infrared light comprises chalcogenide glass.

8. The composite according to claim 7, wherein the chalcogenide glass comprises, in terms of mole percent, 50% to 80% of S, 0% to 40% of Sb, provided that 0% is excluded, 0% to 18% of Ge, provided that 0% is excluded, 0% to 20% of Sn, and 0% to 20% of Bi.

9. The composite according to claim 7, wherein the chalcogenide glass comprises, in terms of mole percent, 4% to 80% of Te, 0% to 50% of Ge, provided that 0% is excluded, and 0% to 20% of Ga.

10. The composite according to claim 1, wherein at least part of the lid body comprises a window capable of transmitting infrared light.

11. The composite according claim 1, wherein at least part of the lid body comprises a lens capable of transmitting infrared light.

12. A hermetic package, comprising:
a base body having a main surface; and
the composite of claim 1 arranged on the main surface of the base body.
